(19) United States
(12) Patent Application Publication
(10) Pub. No.: US 2009/0001549 A1
(43) Pub. Date: Jan. 1, 2009

(54) INTEGRATED CIRCUIT PACKAGE SYSTEM WITH SYMMETRIC PACKAGING

(76) Inventors: Soo-San Park, Seoul (KR); BumJoon Hong, Seoul (KR); Sang-Ho Lee, Kyounggi (KR); Jong-Woo Ha, Seoul (KR)

Correspondence Address: LAW OFFICES OF MIKIO ISHIMARU, 333 W. EL CAMINO REAL, SUITE 330, SUNNYVALE, CA, 94087, US

(21) Appl. No.: 11/772,060

(22) Filed: Jun. 29, 2007

(51) Int. Cl. H01L 23/48; H01L 21/58

(52) U.S. Cl. 257/693; 438/107; 257/E23.011; 257/E21.505

(57) ABSTRACT

An integrated circuit package system comprising: providing a substrate having a first substrate surface and a second substrate surface; forming a first package connector and a second package connector over substantially opposite locations of the first substrate surface and the second substrate surface; and attaching a first integrated circuit and a second integrated circuit adjacent the first package connector over the first substrate surface and the second package connector over the second substrate surface.

### TECHNICAL FIELD

The present invention relates generally to integrated circuit systems, and more particularly to a system for integrated circuit packages.

### BACKGROUND ART

Products using electronic devices and systems have continued to increase across all aspects of our daily lives. With the ever-increasing numbers and scope, the electronic devices further demand increases in storing information and programs. Some of the electronic devices have developed considerable computing ability even within very small areas and dimensional form factors.

These devices can process significant amounts of data or execute sizable programs. Continued development of new application types or functions requires the ability to accommodate additional data or programs for continued use of the existing electronic devices or device form factors.

Wide spread use of portable computers, including laptops, notebooks, palmtops, personal digital assistants, and handheld computers, has been severely hampered by limited capabilities for expansion or customization. Expansion and application customization has been performed through very limited slots for removable expansion modules for I/O, I/O adapters, memories, and memory adapters.

Memory expansion modules have included DRAM, SRAM, ROM, and Flash technologies. I/O expansion modules have included dedicated peripherals, networking, modems, wireless communications, serial I/O, and bar code and other scanners. Having very limited slots meant memory and memory related expansion has been limited to standard product dimensions.

These demands for smaller, higher density memory devices have motivated development of new techniques for producing smaller and less expensive semiconductor devices. One of these technologies involves packaging the integrated circuit memory chip in as efficient a form factor as possible and manufacturing the integrated circuit memory chip as efficiently as possible.

Usually, many individual devices are constructed on the same wafer. When the devices are separated into individual rectangular units, each takes the form of an integrated circuit chip. In order to interface a chip with other circuitry, it is common to mount it with lead fingers and individually connect pad on the chip to the lead fingers using extremely fine wires.

The assemblies are then packaged by individually encapsulating them in molded plastic or ceramic bodies. This results in packaging designs that are more compact, in the physical size and shape of a device, and in a significant increase in overall integrated circuit density. However, integrated circuit density continues to be limited by the area available for mounting chips in a next level system.

To condense the packaging of individual devices, packages have been developed in which more than one device can be packaged at one time at each package site. Each package site is a structure that provides mechanical support for the individual integrated circuit devices. It also provides one or more layers of interconnect lines that enable the devices to be connected electrically to a next level system such as a printed circuit board.

In some cases, multi-chip devices can be fabricated faster and more cheaply than a corresponding single integrated circuit chip, that incorporates all the same functions. Some multi-chip modules have been found to increase circuit density and miniaturization, improve signal propagation speed, reduce overall device size, improve performance, and lower costs.

However, such multi-chip modules can be bulky. Package density is determined by the area required to mount a chip or module on a circuit board. One method for reducing the board size of multi-chip modules and thereby increase their effective density is to stack the chips within the module or package. Such designs are improvements over prior packages that combined components side by side in a horizontal layer.

Across virtually all applications, there continues to be growing demand for increasing capacity. The seemingly endless restrictions and requirements are no more visible than with products in our daily lives. Smaller and denser integrated circuits are expected in many portable electronic products as well as in many larger electronic systems to include more capacity within the same product dimensional form factors.

Thus, a need still remains for an integrated circuit package system to provide improved capacity, higher performance, and reduced size of integrated circuit package. In view of the increasing demand for improved integrated circuit capacity particularly in portable electronic products, it is increasingly critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system comprising: providing a substrate having a first substrate surface and a second substrate surface; forming a first package connector and a second package connector over substantially opposite locations of the first substrate surface and the second substrate surface; and attaching a first integrated circuit and a second integrated circuit adjacent the first package connector over the first substrate surface and the second package connector over the second substrate surface.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a top plan view of an integrated circuit package system without encapsulation in a first embodiment of the present invention;

FIG. 2 is a cross-sectional view of the integrated circuit package system with encapsulation taken along line 2-2 of FIG. 1;

FIG. 3 is a top plan view of an integrated circuit package system without encapsulation in a second embodiment of the present invention;

FIG. 4 is a cross-sectional view of the integrated circuit package system with encapsulation taken along line 4-4 of FIG. 3;

FIG. 5 is a top plan view of an integrated circuit package system without encapsulation in a third embodiment of the present invention;

FIG. 6 is a cross-sectional view of the integrated circuit package system with encapsulation taken along line 6-6 of FIG. 5;

FIG. 7 is a top plan view of an integrated circuit package system in a fourth embodiment of the present invention;

FIG. 8 is a cross-sectional view of the integrated circuit package system taken along line 8-8 of FIG. 7; and

FIG. 9 is a flow chart of an integrated circuit package system for manufacturing the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGS.

Where multiple embodiments are disclosed and described, having some features in common, for clarity and ease of illustration, description, and comprehension thereof, similar and like features one to another will ordinarily be described with like reference numerals. The embodiments may be numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the invention, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “on” as used herein means and refers to direct contact among elements. The term “processing” as used herein includes deposition of material, patterning, exposure, development, etching, cleaning, and/or removal of the material or trimming as required in forming a described structure. The term “system” as used herein means and refers to the method and to the apparatus of the present invention in accordance with the context in which the term is used.

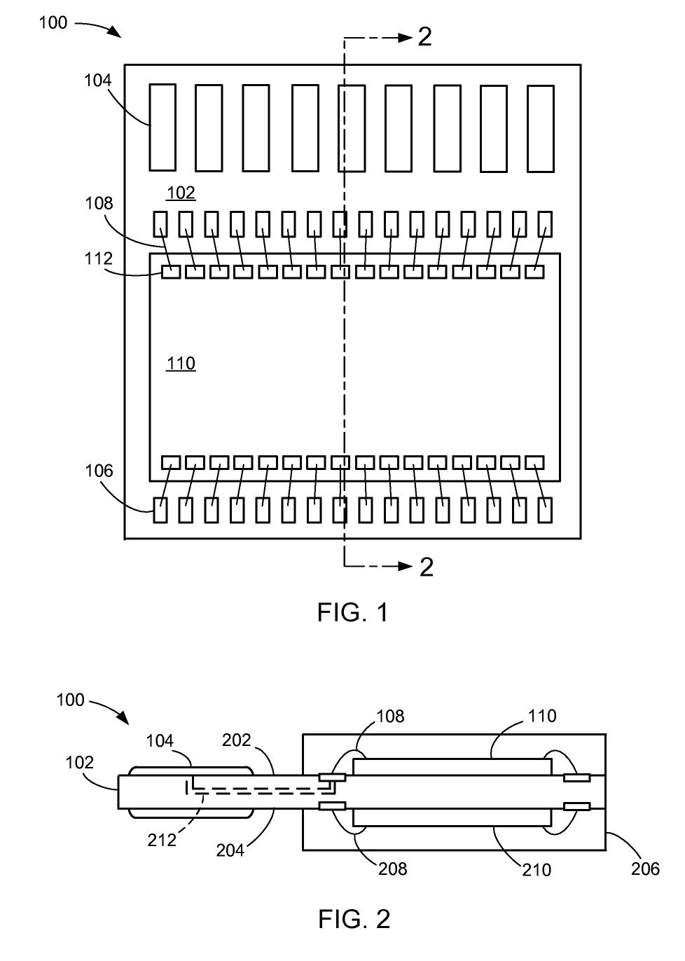

Referring now to FIG. 1, therein is shown a top plan view of an integrated circuit package system 100 without encapsulation in a first embodiment of the present invention. The integrated circuit package system 100 preferably includes a substrate 102, package connectors 104, and package leads 106. First die connectors 108 can provide electrical connectivity to a first integrated circuit 110 such as a memory device or other device with cooperative or compatible inputs or outputs and the package leads 106.

Die connection sites 112 such as bond pads of the first integrated circuit 110 can be electrically connected to the package connectors 104 or other devices in the integrated circuit package system 100. The die connection sites 112 can preferably be formed as two parallel rows, one each adjacent opposite edges of the first integrated circuit 110. The package leads 106 can preferably be formed as two parallel rows, one row adjacent the package connectors 104 and the die connection sites 112 adjacent opposite edges of the first integrated circuit 110.

The first integrated circuit 110 and the first die connectors 108 can be attached over the substrate 102 and adjacent the package leads 106. The package connectors 104 are preferably substantially exposed on the substrate 102 adjacent the package leads 106 and the first integrated circuit 110. The package connectors 104 can provide electrical connectivity to a next level system such as another package, a printed circuit board, or a system connector.

For illustrative purposes, the integrated circuit package system 100 is shown having one integrated circuit die on a side of the substrate 102 although it is understood that any number of integrated circuit die may be used with packaging technologies such as with an inner stacking module (ISM), a package on package (PoP) or a three-dimensional (3D).

Referring now to FIG. 2 therein is shown a cross-sectional view of the integrated circuit package system 100 with encapsulation taken along line 2-2 of FIG. 1. The integrated circuit package system 100 preferably includes the substrate 102 having a first substrate surface 202 and a second substrate surface 204.

An encapsulant 206 can be formed over the first substrate surface 202 or the second substrate surface 204. The encapsulant 206 can be formed of the same or different materials over the first substrate surface 202 or the second substrate surface 204. Further, the encapsulant 206 can optionally be applied with the same or different process over the first substrate surface 202 or the second substrate surface 204.

The first integrated circuit 110 can be attached over the first substrate surface 202 and electrically connected with the first die connectors. Second die connectors 208 can electrically connect a second integrated circuit 210 such as a memory device or other device with cooperative or compatible inputs or outputs can be attached over the second substrate surface 204.

The second integrated circuit 210 can be electrically connected with the second die connectors 208. The first die connectors 108 and the second die connectors 208 can provide electrical connectivity to the first integrated circuit 110, the second integrated circuit 210, or the package connectors 104 with substrate connections 212 such as routing or traces.

The package connectors 104 are preferably formed over the first substrate surface 202 and the second substrate surface 204 adjacent an edge of the substrate 102. The package connectors 104 over the first substrate surface 202 are substantially opposite the package connectors 104 over the second substrate surface 204.

The first integrated circuit 110 and the second integrated circuit 210 are attached adjacent an edge of the substrate 102 opposite the package connectors 104. The first integrated circuit 110 is substantially opposite the second integrated circuit 210 symmetrically assembling a symmetric package.

The encapsulant 206 can be applied over the first integrated circuit 110, the first die connectors 108, and the package leads on the first substrate surface 202. In a similar manner, the encapsulant 206 can be applied over the second integrated circuit 210, the second die connectors 208, and the package leads 106 on the second substrate surface 204.

For illustrative purposes, the integrated circuit package system 100 is shown having one integrated circuit die over each of the first substrate surface 202 and the second substrate surface 204 although it is understood that any number of integrated circuit die may be used.

It has been discovered that the integrated circuit package system 100 with symmetric packaging provides increased memory capacity, a symmetric structure for balancing memory, and two way docking interconnect for stability.

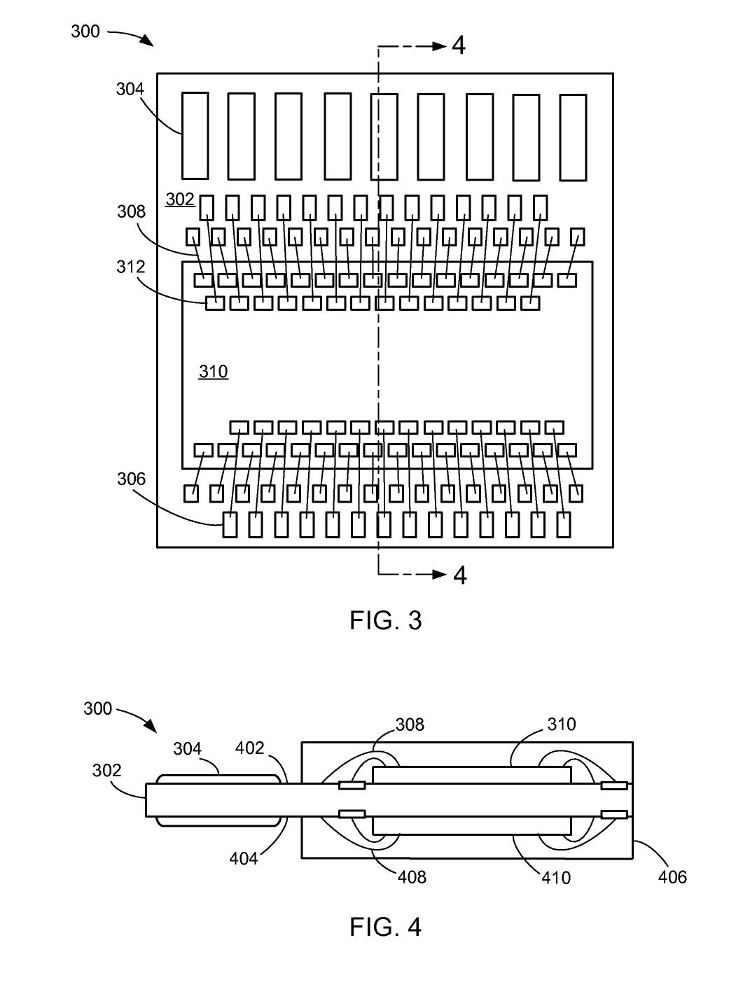

Referring now to FIG. 3, therein is shown a top plan view of an integrated circuit package system 300 without encapsulation in a second embodiment of the present invention. The integrated circuit package system 300 preferably includes a substrate 302, package connectors 304, and package leads 306. First die connectors 308 can provide electrical connectivity to a first integrated circuit 310 such as a memory device or other device with cooperative or compatible inputs or outputs and the package leads 306.

First die connection sites 312 such as bond pads of the first integrated circuit 310 can be electrically connected to the package connectors 304 or other devices in the integrated circuit package system 300. The first die connection sites 312 can be formed in any configuration such as two sets of two parallel rows. The first die connection sites 312 can preferably be formed as four rows, two parallel rows each adjacent opposite edges of the first integrated circuit 3 10. The package leads 306 can preferably be formed as four rows, two parallel rows adjacent the package connectors 304 and the first die connection sites 312 adjacent opposite edges of the first integrated circuit 3 10.

The first integrated circuit 310 and the first die connectors 308 can be attached over the substrate 302 and adjacent the package leads 306. The package connectors 304 are preferably substantially exposed on the substrate 302 adjacent the package leads 306 and the first integrated circuit 3 10. The package connectors 304 can provide electrical connectivity to a next level system such as another package, a printed circuit board, or a system connector.

For illustrative purposes, the integrated circuit package system 300 is shown having two sets of two parallel rows with the first die connection sites 312 and the package leads 306 staggered although it is understood that the rows may be in any configuration.

Referring now to FIG. 4, therein is shown a cross-sectional view of the integrated circuit package system 300 with encapsulation taken along line 4-4 of FIG. 3. The integrated circuit package system 300 preferably includes the substrate 302 having a first substrate surface 402 and a second substrate surface 404.

An encapsulant 406 can be formed over the first substrate surface 402 or the second substrate surface 404. The encapsulant 406 can be formed of the same or different materials over the first substrate surface 402 or the second substrate surface 404. Further, the encapsulant 406 can optionally be applied with the same or different process over the first substrate surface 402 or the second substrate surface 404.

The first integrated circuit 310 can be attached over the first substrate surface 402 and electrically connected with the first die connectors. Second die connectors 408 can electrically connect a second integrated circuit 410 such as a memory device or other device with cooperative or compatible inputs or outputs can be attached over the second substrate surface 404.

The second integrated circuit 410 can be electrically connected with the second die connectors 408. The first die connectors 308 and the second die connectors 408 can provide electrical connectivity to the first integrated circuit 310, the second integrated circuit 410, or the package connectors 304.

The package connectors 304 are preferably formed over the first substrate surface 402 and the second substrate surface 404 adjacent an edge of the substrate 302. The package connectors 304 over the first substrate surface 402 are substantially opposite the package connectors 304 over the second substrate surface 404.

The first integrated circuit 310 and the second integrated circuit 410 are attached adjacent an edge of the substrate 302 opposite the package connectors 304. The first integrated circuit 310 is substantially opposite the second integrated circuit 410 symmetrically assembling a symmetric package.

The encapsulant 406 can be applied over the first integrated circuit 310, the first die connectors 308, and the package leads on the first substrate surface 402. In a similar manner, the encapsulant 406 can be applied over the second integrated circuit 410, the second die connectors 408, and the package leads 306 on the second substrate surface 404.

For illustrative purposes, the integrated circuit package system 300 is shown having one integrated circuit die over each of the first substrate surface 402 and the second substrate surface 404 although it is understood that any number of integrated circuit die may be used.

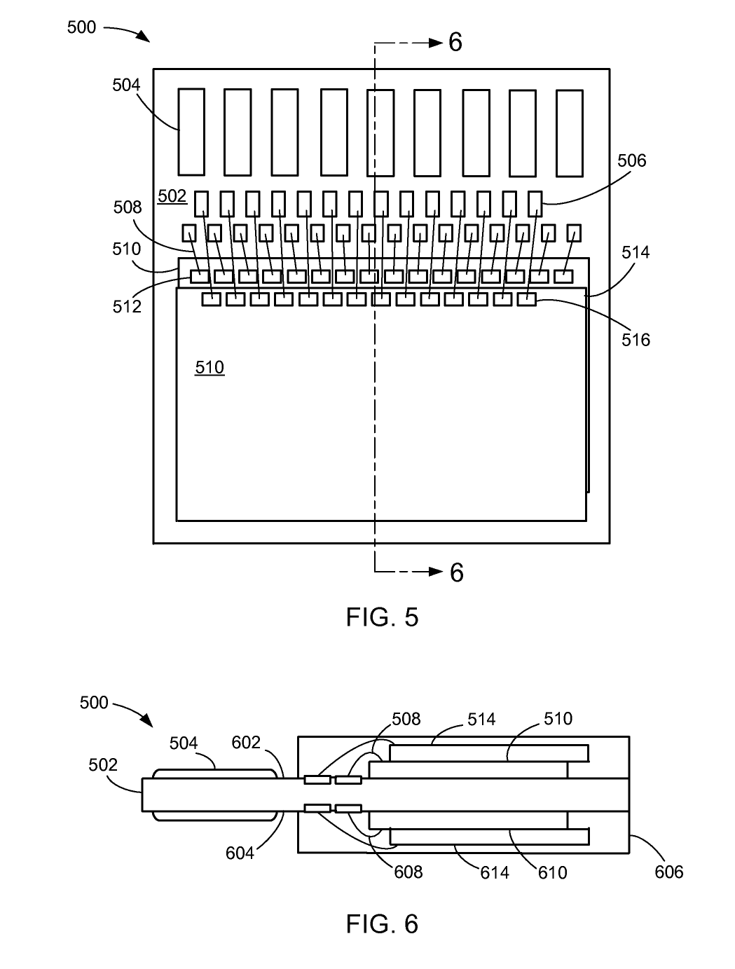

Referring now to FIG. 5, therein is shown a top plan view of an integrated circuit package system 500 without encapsulation in a third embodiment of the present invention. The integrated circuit package system 500 preferably includes a substrate 502, package connectors 504, and package leads 506. First die connectors 508 can provide electrical connectivity to a first integrated circuit 510 such as a memory device or other device with cooperative or compatible inputs or outputs and the package leads 506.

First die connection sites 512 such as bond pads of the first integrated circuit 510 can be electrically connected to the package connectors 504 or other devices in the integrated circuit package system 500. The first die connection sites 512 can be formed in any configuration such as a row. The first die connection sites 512 can preferably be formed as a row adjacent one edge of the first integrated circuit 510. The package leads 506 can preferably be formed as a row adjacent the package connectors 504 and the first die connection sites 512 adjacent one edge of the first integrated circuit 510.

A second integrated circuit 514 can be attached over the first integrated circuit 510. Second die connection sites 516 of the second integrated circuit 514 can be electrically connected to the package connectors 504 or other devices in the integrated circuit package system 500. The second die connection sites 516 can be formed in any configuration such as a row. The second die connection sites 516 can preferably be formed as a row adjacent one edge of the second integrated circuit 514. The package leads 506 can preferably be formed as a row adjacent the package connectors 504 and the first die connection sites 512 adjacent one edge of the first integrated circuit 5 10.

The first integrated circuit 510 and the first die connectors 508 can be attached over the substrate 502 and adjacent the package leads 506. The package connectors 504 are preferably substantially exposed on the substrate 502 adjacent the package leads 506 and the first integrated circuit 5 10. The package connectors 504 can provide electrical connectivity to a next level system such as another package, a printed circuit board, or a system connector.

For illustrative purposes, the integrated circuit package system 500 is shown having two parallel rows with the first die connection sites 512 and the package leads 506 substantially aligned although it is understood that the rows may be in any configuration.

Referring now to FIG. 6, therein is shown a cross-sectional view of the integrated circuit package system 500 with encapsulation taken along line 6-6 of FIG. 5. The integrated circuit package system 500 preferably includes the substrate 502 having a first substrate surface 602 and a second substrate surface 604.

An encapsulant 606 can be formed over the first substrate surface 602 or the second substrate surface 604. The encapsulant 606 can be formed of the same or different materials over the first substrate surface 602 or the second substrate surface 604. Further, the encapsulant 606 can optionally be applied with the same or different process over the first substrate surface 602 or the second substrate surface 604.

The first integrated circuit 510 can be attached over the first substrate surface 602 and electrically connected with the first die connectors 508. Third die connectors 608 can electrically connect a third integrated circuit 610 such as a memory device or other device with cooperative or compatible inputs or outputs can be attached over the second substrate surface 604.

The third integrated circuit 610 can be electrically connected with the third die connectors 608. The first die connectors 508 and the third die connectors 608 can provide electrical connectivity to the first integrated circuit 510, the third integrated circuit 610, or the package connectors 504.

The second integrated circuit 514 can be attached over the first integrated circuit 510 and electrically connected with the first die connectors 508. In a similar manner, a fourth integrated circuit 614 can be attached over the third integrated circuit 610 and electrically connected with the third die connectors 608.

The package connectors 504 are preferably formed over the first substrate surface 602 and the second substrate surface 604 adjacent an edge of the substrate 502. The package connectors 504 over the first substrate surface 602 are substantially opposite the package connectors 504 over the second substrate surface 604.

The first integrated circuit 510, the second integrated circuit 514, the third integrated circuit 610 and the fourth integrated circuit 614 are attached adjacent an edge of the substrate 502 opposite the package connectors 504. The first integrated circuit 510 and the second integrated circuit 514 are substantially opposite the third integrated circuit 610 and the fourth integrated circuit 614 symmetrically assembling a symmetric package.

The encapsulant 606 can be applied over the first integrated circuit 510, the second integrated circuit 514, the first die connectors 508, and the package leads on the first substrate surface 602. In a similar manner, the encapsulant 606 can be applied over the third integrated circuit 610, the fourth integrated circuit 614, the third die connectors 608, and the package leads 506 on the second substrate surface 604.

For illustrative purposes, the integrated circuit package system 500 is shown having two integrated circuit die over each of the first substrate surface 602 and the second substrate surface 604 although it is understood that any number of integrated circuit die may be used.

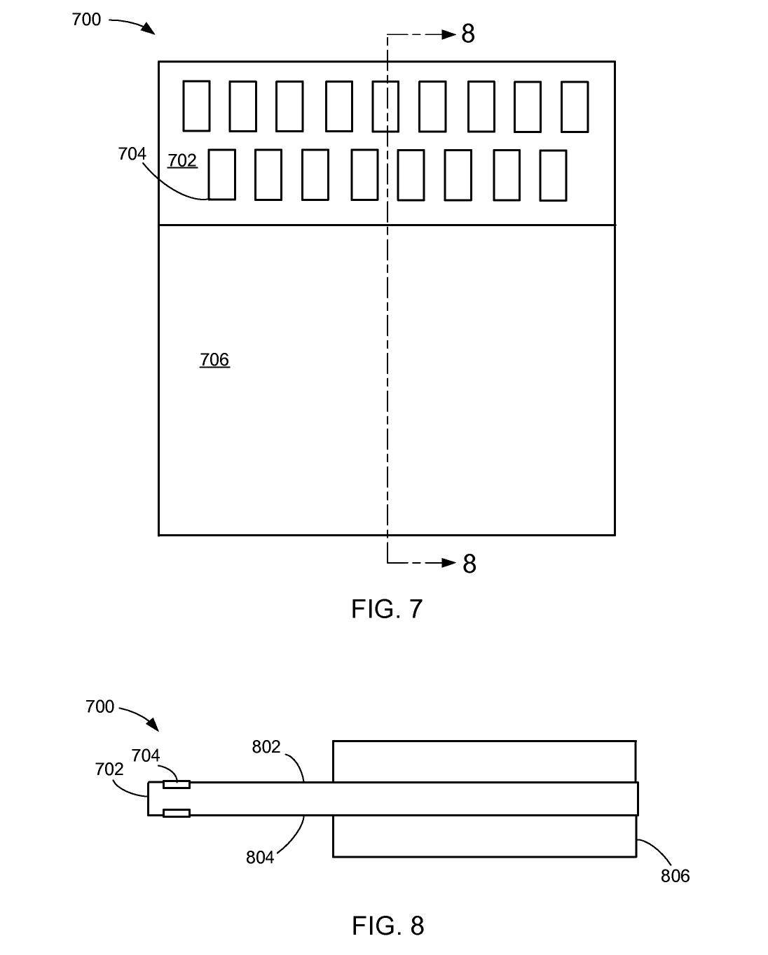

Referring now to FIG. 7, therein is shown a top plan view of an integrated circuit package system 700 in a fourth embodiment of the present invention. The integrated circuit package system 700 preferably includes a substrate 702 and package connectors 704. A molded body 706 can be formed over a portion of the substrate 702 adjacent the package connectors 704.

The package connectors 704 can be formed over or embedded in the substrate 702. Two rows of the package connectors 704 can be preferably formed in a parallel configuration adjacent an edge of the substrate 702. Further, can be formed with the package connectors 704 of one row having an offset or stagger from the package connectors 704 of another row.

The package connectors 704 are preferably substantially exposed from the molded body 706 to provide electrical connectivity to a next level system such as another package, a printed circuit board, or a system connector. The molded body 706 provides structural integrity and protection to integrated circuit die, connectors, leads, or other components.

As would be obvious to one of ordinary skill in the art, the molded body 706 or configuration of the package connectors 704 can be applied to any embodiment of the present invention. For illustrative purposes, the package connectors 704 are shown staggered although it is understood that the package connectors 704 may be substantially aligned or in any other configuration.

Referring now to FIG. 8, therein is shown a cross-sectional view of the integrated circuit package system 700 taken along line 8-8 of FIG. 7. The integrated circuit package system 700 preferably includes the substrate 702 having a first substrate surface 802 and a second substrate surface 804.

The package connectors 704 are preferably formed over the first substrate surface 802 and the second substrate surface 804 adjacent an edge of the substrate 702. The package connectors 704 over the first substrate surface 802 are substantially opposite the package connectors 704 over the second substrate surface 804 symmetrically assembling a symmetric package.

The molded body 706 can be formed with a molding material 806 over the first substrate surface 802 or the second substrate surface 804. The molding material 806 can be formed of the same or different materials over the first substrate surface 802 or the second substrate surface 804. Further, the molding material 806 can optionally be applied with the same or different process over the first substrate surface 802 or the second substrate surface 804.

The molding material 806 can be applied over components on the first substrate surface 802. In a similar manner, the molding material 806 can be applied over components on the second substrate surface 804.

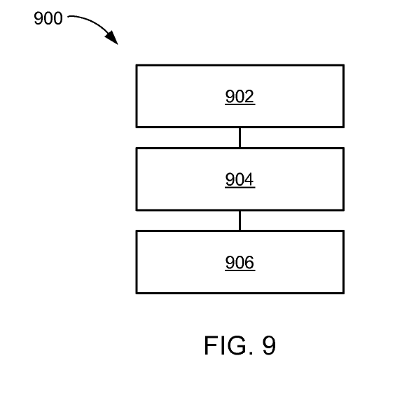

Referring now to FIG. 9, therein is shown a flow chart of an integrated circuit package system 900 for manufacturing the integrated circuit package system 100 in an embodiment of the present invention. The system 900 includes providing a substrate having a first substrate surface and a second substrate surface in a block 902; forming a first package connector and a second package connector over substantially opposite locations of the first substrate surface and the second substrate surface in a block 904; and attaching a first integrated circuit and a second integrated circuit adjacent the first package connector over the first substrate surface and the second package connector over the second substrate surface in a block 906.

In greater detail, a system to provide the method and apparatus of the integrated circuit package system 100, in an embodiment of the present invention, is performed as follows:
1. Providing a substrate having a first substrate surface and a second substrate surface.
2. Forming a first and second package connector over substantially opposite locations of the first substrate surface and the second substrate surface.
3. a first integrated circuit and a second integrated circuit adjacent the first package connector over the first substrate surface and the second package connector over the second substrate surface.
4. Forming an encapsulant over the first integrated circuit and the second integrated circuit leaving the package connector substantially exposed.

Thus, it has been discovered that the integrated circuit package system method and apparatus of the present invention furnish important and heretofore unknown and unavailable solutions, capabilities, and functional aspects. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit package system comprising:
providing a substrate having a first substrate surface and a second substrate surface;
forming a first package connector and a second package connector over substantially opposite locations of the first substrate surface and the second substrate surface; and
attaching a first integrated circuit and a second integrated circuit adjacent the first package connector over the first substrate surface and the second package connector over the second substrate surface.

2. The system as claimed in claim 1 wherein attaching the first integrated circuit includes:
forming the first integrated circuit having die connection sites as two parallel rows adjacent opposite edges of the first integrated circuit; and
attaching the first integrated circuit adjacent package leads formed as two parallel rows, one row adjacent the first package connector.

3. The system as claimed in claim 1 wherein attaching the first integrated circuit includes:
forming the first integrated circuit having die connection sites as a row adjacent one edge of the first integrated circuit; and
attaching the first integrated circuit adjacent package leads formed as a row adjacent the first package connector.

4. The system as claimed in claim 1 wherein forming the first package connector and the second package connector includes forming an interconnect.

5. The system as claimed in claim 1 further comprising applying an encapsulant over the first integrated circuit.

6. An integrated circuit package system comprising:
providing a substrate having a first substrate surface and a second substrate surface;
forming a first package connector and a second package connector over substantially opposite locations of the first substrate surface and the second substrate surface;
attaching a first integrated circuit and a second integrated circuit adjacent the first package connector over the first substrate surface and the second package connector over the second substrate surface; and
forming an encapsulant over the first integrated circuit and the second integrated circuit leaving the first package connector and the second package connector substantially exposed.

7. The system as claimed in claim 6 wherein attaching the first integrated circuit includes:
forming the first integrated circuit having die connection sites as four parallel rows, each of two rows adjacent opposite edges of the first integrated circuit; and
attaching the first integrated circuit adjacent package leads formed as four parallel rows, two rows adjacent the first package connector.

8. The system as claimed in claim 6 wherein forming the first package connector includes:
forming a first row of the first package connector adjacent an edge of the substrate; and
forming a second row of the first package connector in parallel to and having an offset from the first row.

9. The system as claimed in claim 6 wherein forming the first package connector and the second package connector includes forming a two way docking interconnect.

10. The system as claimed in claim 6 wherein forming the encapsulant includes forming a molded body.

11. An integrated circuit package system comprising:
a substrate having a first substrate surface and a second substrate surface;
a first package connector over the first substrate surface;
a second package connector over a substantially opposite location of the second substrate surface from the first integrated circuit;
a first integrated circuit over the first substrate surface adjacent the first package connector; and
a second integrated circuit over the second substrate surface, adjacent the second package connector, and substantially opposite the first integrated circuit.

12. The system as claimed in claim 11 wherein the first integrated circuit has die connection sites formed as two parallel rows adjacent opposite edges of the first integrated circuit, wherein the first integrated circuit is adjacent package leads formed as two parallel rows, one row adjacent the first package connector.

13. The system as claimed in claim 11 wherein the first integrated circuit has die connection sites formed as a row adjacent one edge of the first integrated circuit, wherein the first integrated circuit is adjacent package leads formed as a row adjacent the first package connector.

14. The system as claimed in claim 11 wherein the first package connector and the second package connector form an interconnect.

15. The system as claimed in claim 11 further comprising an encapsulant over the first integrated circuit.

16. The system as claimed in claim 11 further comprising:
an encapsulant over the first integrated circuit and the second integrated circuit leaving the first package connector and the second package connector substantially exposed.

17. The system as claimed in claim 16 wherein the first integrated circuit has die connection sites formed as four parallel rows, each of two rows adjacent opposite edges of the first integrated circuit, wherein the first integrated circuit is adjacent package leads formed as four parallel rows, two rows adjacent the first package connector.

18. The system as claimed in claim 16 wherein the first package connector includes:
a first row of the first package connector adjacent an edge of the substrate; and
a second row of the first package connector in parallel to and having an offset from the first row.

19. The system as claimed in claim 16 wherein the first package connector and the second package connector include a two way docking interconnect.

20. The system as claimed in claim 16 wherein the encapsulant includes a molded body.
